(19) United States
(12) Patent Application Publication
(10) Pub. No.: US 2011/0193734 A1
(43) Pub. Date: Aug. 11, 2011

(54) SIGNAL CONVERTER, PARAMETER DECIDING DEVICE, PARAMETER DECIDING METHOD, PROGRAM, AND RECORDING MEDIUM

(75) Inventors: Satoshi Hironaka, Fukuoka (JP); Tohru Kohda, Fukuoka (JP); Kazuyuki Aihara, Chiba (JP)

(73) Assignees: JAPAN SCIENCE AND TECHNOLOGY AGENCY, Kawaguchi-shi, Saitama (JP); KYUSHU UNIVERSITY, NATIONAL UNIVERSITY CORPORATION, Fukuoka-shi, Fukuoka (JP)

(21) Appl. No.: 13/060,338

(22) PCT Filed: Aug. 21, 2009
(86) PCT No.: PCT/JP2009/064632

§ 371 Date: Feb. 23, 2011

(30) Foreign Application Priority Data
Aug. 25, 2008 (JP) 2008-214819

(51) Int. Cl. H03M 1/12

(52) U.S. Cl. 341/155

(57) ABSTRACT

A signal converter and the like, which can more accurately and stably realize signal conversion between an analog signal and a digital signal are proposed. In a β-encoder, when a logic value generated by at least a quantizer 7 is 1, a signal generation unit 11 generates a feedback signal from an amplified signal generated by an amplifier 5 and a power source signal generated by a power source 9, and the signal generation unit 11 adds the feedback signal to an input signal. Therefore, for example, the β-encoder having robustness to fluctuation of a quantizer 7 can be realized. Further, the more-stable β-encoder can be realized by a negative β-encoder that generates the feedback signal using a signal obtained by inverting a sign of the amplified signal. Optimum designs of the amplifier 5 and power source 9 can also be realized.

### TECHNICAL FIELD

The present invention relates to a signal converter, a parameter deciding device, a parameter deciding method, a program, and a recording medium, and particularly relates to a signal converter or the like that outputs a bit sequence in response to an input signal.

### BACKGROUND ART

Analog-to-Digital (A/D) conversion is a basic technology behind various technologies. Phases of the A/D conversion consist of sampling and quantization. A sampling theorem guarantees that a signal can be completely reconstructed with a sampled value. The quantization is a process of encoding the sampled value where quantization error inevitably arises.

FIG. 9(a) is a block diagram illustrating an outline of PCM (Pulse Code Modulation) and FIG. 9(b) is a view illustrating a map of the PCM. As illustrated in FIG. 9(b), y=x (line 115), a line (line 116) connecting an origin and (½, 1), and a line (line 117) connecting (½, 0) and (1, 1) are used in the PCM. As illustrated in FIG. 9(b), the PCM realizes the Bernoulli shift map.

FIG. 10(a) is a block diagram illustrating an outline of a β-encoder and FIG. 10(b) is a view illustrating a map of the β-encoder. As illustrated in FIG. 10(b), y=x (line 145), as well as a line (line 146) connecting the origin and (γ(β−1)⁻¹, 1) and a line (line 147) connecting (γ, 0) and (1, 1) which are classified by x=γν, are used in the β-encoder. The β-encoder is based on β-expansion. I. Daubechies, et al. introduced an A/D converter having robustness to fluctuation of a quantization threshold and that of an amplifier (see Non-Patent Document 1, hereinafter referred to as a “conventional β-encoder”).

The inventors further proposed a β-encoder by refining the conventional β-encoder (see Patent Document 1 and Non-Patent Document 2).

### PRIOR ART DOCUMENTS

### Patent Document

Patent Document 1: PCT/JP2008/62897

### Non-Patent Documents

Non-Patent Document 1: I. Daubechies, and three others, “A/D Conversion With Imperfect Quantizers,” IEEE Transactions on Information Theory, vol. 52, no. 3, pp. 874-885, March 2006.
Non-Patent Document 2: S, Hironaka, and two others, “Markov chain of binary sequences generated by A/D conversion using β encoder”, Proc. of 15th IEEE International Workshop on Nonlinear Dynamics of Electronic Systems, pp. 261-264, 2007

### SUMMARY OF THE INVENTION

### Problem to be Solved by the Invention

However, the A/D converter is an analog circuit. A parameter of a circuit component (such as a quantizer or an amplifier) is possibly fluctuated. Therefore, it is necessary to disclose a mathematical structure in consideration of the fluctuation of the circuit component as a practical problem.

For example, the PCM has high accuracy although it is unstable. FIG. 11 is a view illustrating a case in which a threshold fluctuates in the PCM. When the line 116 and the line 117 of FIG. 9(b) become a line 118 and a line 119 due to the fluctuation of the threshold as illustrated in FIG. 11(a), a map thereof diverges as illustrated in FIG. 11(b). Then, the quantization error does not converge, thereby fails in the A/D conversion. Thus, the PCM does not have the robustness to the fluctuation of the quantization threshold.

The conventional β-encoder is an A/D converter in which the fluctuation of the circuit component is considered. However, a lower limit of an interval is set to a decoded value. Therefore, the quantization error is insufficiently reduced in the conventional β-encoder.

The β-encoder proposed by the inventors is an A/D converter in which the fluctuation of the circuit component is considered similarly to the conventional β-encoder. A middle point of the interval is set to the decoded value, whereby the quantization error is reduced, compared with the conventional β-encoder. However, the β-encoder proposed by the inventors presents only an optimum design guideline for the quantizer, and does not present an optimum design guideline for the amplifier.

In view of the foregoing, it is an object of the present invention to propose a signal converter, a parameter deciding device, a parameter deciding method, a program, and a recording medium that can realize more accurate and stable signal conversion between an analog signal and a digital signal.

### Means for Solving the Problem

A first aspect in accordance with the present invention provides a signal converter that outputs a bit sequence in response to an input signal, the signal converter comprising a feedback unit that generates a composite signal by adding a feedback signal to the input signal, the feedback signal being generated according to a value of the output bit sequence, an amplifier that multiplies the composite signal by β (β>1) to generate an amplified signal, and a quantizer that quantizes the amplified signal into a logic value 0 or a logic value 1 and thereby outputs a new bit, wherein the feedback unit includes a power source that generates a power source signal, a signal generation unit that generates the feedback signal at least by use of the amplified signal when the logic value 0 is output from the quantizer, and generates the feedback signal by use of the amplified signal and the power source signal when the logic value 1 is output from the quantizer, and an adder that adds the feedback signal to the input signal.

A second aspect in accordance with the present invention provides the signal converter according to the first aspect, wherein the signal generation unit generates the feedback signal by subtracting the amplified signal from the power source signal when the logic value 0 is output from the quantizer, and the signal generation unit generates the feedback signal by subtracting the amplified signal from a signal obtained by β-multiplying the power source signal when the logic value 1 is output from the quantizer.

A third aspect in accordance with the present invention provides the signal converter according to the first aspect, wherein the signal generation unit generates the feedback signal as being equal to the amplified signal when the logic value 0 is output from the quantizer, and the signal generation unit generates the feedback signal by subtracting a signal obtained by β-multiplying the power source signal from sum of the amplified signal and the power source signal when the logic value 1 is output from the quantizer.

A fourth aspect in accordance with the present invention provides the signal converter according to any one of the first aspect, the second aspect and the third aspect, wherein a parameter β of the amplifier is 2L/(L+1) with respect to a number of bits L of the bit sequence output by the signal converter, and/or a parameter s of the power source signal generated by the power source is σ_{β,s}(L+1)/2 with respect to quantiser tolerance σ_{βs}.

A fifth aspect in accordance with the present invention provides a parameter deciding device that decides a parameter in the signal converter as in any one of the first aspect, the second aspect and the third aspect, the parameter deciding device comprising a set value storage unit that stores a number of bits L of the bit sequence output by the signal converter and a quantiser tolerance σ_{βs} of the signal converter, and a parameter deciding unit that decides a parameter β of the amplifier of the signal converter and a parameter s of the power source signal generated by the power source of the signal converter by β=2L/(L+1) and s=σ_{β,s}(L+1)/2, respectively, and correcting β=2L/(L+1) and s=σ_{β,s}(L+1)/2 to β=2−1/σ_{β,s} and s=1 when the parameter s satisfies s≦1.

A sixth aspect in accordance with the present invention provides a parameter deciding method for a parameter deciding device that decides a parameter in the signal converter as in any one of the first aspect, the second aspect and the third aspect, wherein the parameter deciding device includes a set value storage unit that stores a number of bits L of the bit sequence output by the signal converter, and a parameter deciding unit of the parameter deciding device that decides that a parameter β of the amplifier of the signal converter is 2L/(L+1).

A seventh aspect in accordance with the present invention provides a parameter deciding method for a parameter deciding device that decides a parameter in the signal converter as in any one of the first aspect, the second aspect and the third aspect, wherein the parameter deciding device includes a set value storage unit that stores quantiser tolerance σ_{βs} of the signal converter, the set value storage unit further stores a number of bits L of the bit sequence output by the signal converter or the parameter β of the amplifier of the signal converter, and a parameter deciding unit of the parameter deciding device decides a parameter s of the power source signal generated by the power source of the signal converter between σ_{β,s}(L+1)/2 and σ_{β,s}/(2−β).

An eighth aspect in accordance with the present invention provides a program that causes a computer to perform the parameter deciding method according to the sixth aspect or the seventh aspect.

A ninth aspect in accordance with the present invention provides a computer-readable recording medium in which the program according to the eighth aspect is recorded.

In each of the aspects, the signal generation unit may generate a feedback signal from an amplified signal and a power source signal when a logic value is 0. Or the signal generation unit may generate the feedback signal from the amplified signal and the power source signal both when the logic value is 0 and when the logic value is 1.

In each of the aspects, the specific examples of the power source are a voltage source or a current source. And the parameter s indicates, for example, a voltage in a constant voltage source or a current in a constant current source. In the fifth to the tenth aspects, σ_{β,s} is, for example, a quantiser tolerance of the quantizer. In the signal generation unit, the signal obtained by β-multiplying the power source signal may be obtained by β-multiplying the power source signal with use of the same amplifier as the amplifier that β-multiplies the composite signal.

### Effect of the Invention

In the signal converter, the fluctuation from the set value at the designing stage is inevitable in each of the parameter β of the amplifier and the threshold ν of the quantizer at the production stage. Therefore, the control of the fluctuation becomes an issue. In the conventional β-encoder, the quantiser tolerance is (β−1)⁻¹−1, which depends only on β. Therefore, the fluctuation of the threshold cannot freely be set.

In each of the aspects of the present invention, at least when the logic value generated by the quantizer is 1, the signal generation unit of the feedback unit generates the feedback signal from not only the amplified signal but also the power source signal generated by the power source. Particularly, in each of the second aspect and the third aspect of the present invention, when the logic value is 1, the signal generation unit generates the feedback signal by subtracting the amplified signal from the signal that is obtained by p-multiplying the power source signal (or, vice versa, by subtracting the signal obtained by p-multiplying the power source signal from the amplified signal). Therefore, the negative β-encoder and the scaled β-encoder can be realized, and the scale adjusting function for the scale s can be achieved by the parameter s of the power source signal in the signal converter. Further, the optimum design guideline for the amplifier can be obtained. Particularly, as in the fifth aspect of the present invention and the like, the optimum design of the amplifier can be realized according to the number of bits L (bit budget) of the bit sequence output by the signal converter according to any one of the first to the fourth aspects of the present invention. Further, the optimum design of the power source can be realized according to the quantiser tolerance σ_{βs}.

Further, as in the second aspect of the present invention, the signal generation unit of the feedback unit generates the feedback signal using the signal obtained by multiplying the amplified signal by −1, which allows the negative β-encoder to be realized. Therefore, more stable A/D conversion can be realized.

### BRIEF DESCRIPTION OF THE DRAWINGS

FIG. 1 is a schematic block diagram illustrating an outline of a signal converter 1 according to an embodiment of the present invention.

FIG. 2 illustrates quantization error for a quantization threshold ν with respect to a steady state when a lower limit of an interval is set to a decoded value, a steady state when a middle point of the interval is set to the decoded value, and a transient state when the middle point of the interval is set to the decoded value.

FIG. 3(a) is a schematic block diagram illustrating a signal converter 21 as an example of a scaled β-encoder, and FIG. 3(b) is a view illustrating a map of the signal converter 21.

FIG. 4 is a schematic block diagram illustrating an example of a parameter deciding device 81 that decides a parameter.

FIG. 5(a) is a schematic block diagram illustrating an outline of a signal converter 41 as an example of the scaled β-encoder to which a negative p-map is introduced, and FIG. 5(b) is a view illustrating a map of the signal converter 41.

FIG. 6 illustrates an invariant subinterval of positive β-expansion.

FIG. 7 illustrates (A) variance by a β-encoder to which a D/A conversion method of Daubechies is adopted, (B) variance by a positive β-encoder, and (C) variance by a negative β-encoder, with respect to the quantization threshold ν.

FIG. 8 illustrates error between a root of a characteristic equation of β and β in cases of (A) an characteristic equation P_{Daub}(γ) of Daubechies, (B) an characteristic equation P_{β}(γ) of the positive β-encoder, and (c) an characteristic equation P_{Nβ}(γ) of the negative β-encoder.

FIG. 9(a) is a block diagram illustrating an outline of conventional PCM, and FIG. 9(b) illustrates a map of the conventional PCM.

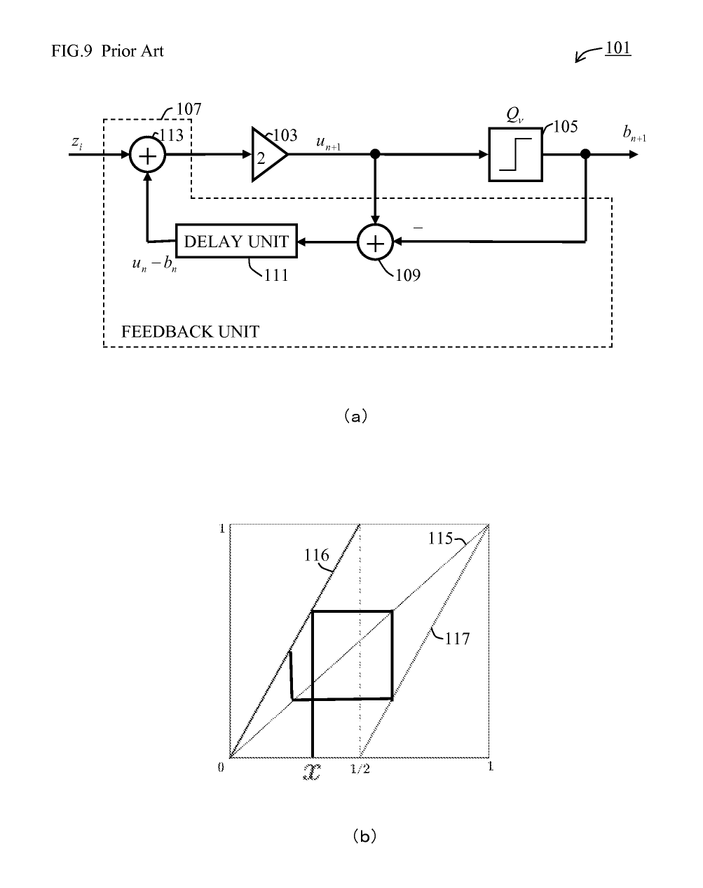

FIG. 10(a) is a block diagram illustrating an outline of a conventional β-encoder, and FIG. 10(b) illustrates a map of the conventional β-encoder.

FIG. 11 illustrates a state in which a threshold fluctuates in the PCM of FIG. 9.

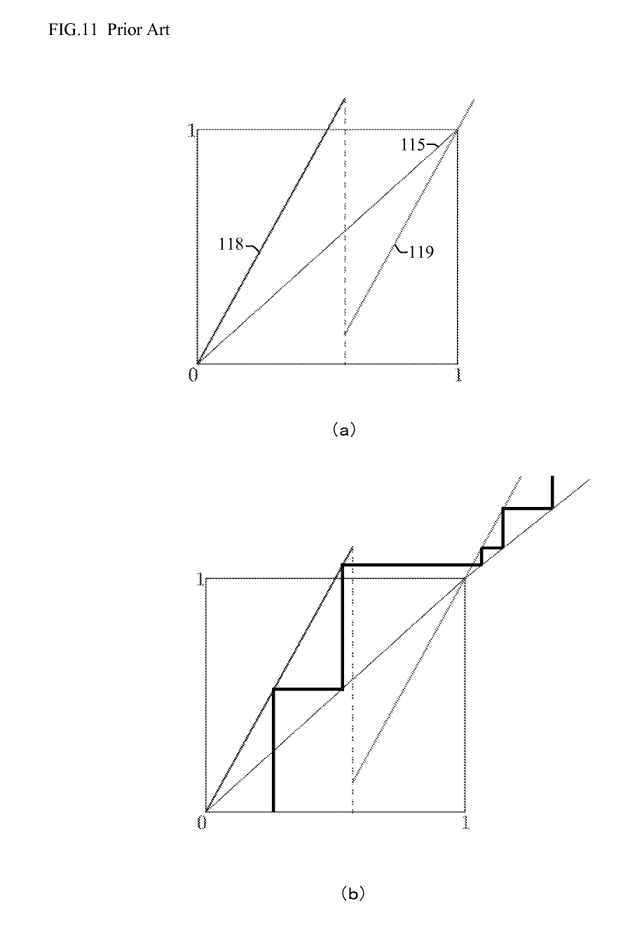

### MODES FOR CARRYING OUT THE INVENTION

Embodiments of the present invention will be described below with reference the drawings. The present invention is not limited to the following embodiments.

### First Embodiment

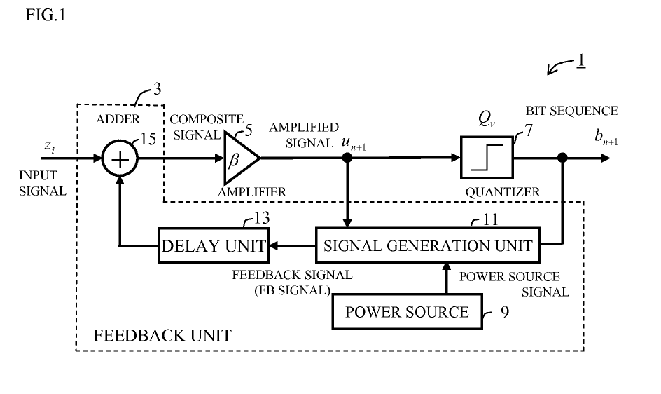

FIG. 1 is a schematic block diagram illustrating an outline of a signal converter 1 according to an embodiment of the present invention. The signal converter 1 outputs a bit sequence {bₙ} in response to an input signal zᵢ. The input signal zᵢ is set to a sampled value for z₀ and zero for zᵢ (i>0). The signal converter 1 performs computation by L-time feedback while zᵢ is zero (a no-input period), thereby obtaining pieces of L-bit information b₁, . . . , b_{L}. Hereinafter the number ‘i’ indicates the time for sampling process, on the contrary, the number ‘n’ implies the clock time for quantization process using feedback loop.

The signal converter 1 includes a feedback unit 3, an amplifier 5, and a quantizer 7. The feedback unit 3 generates a signal according to a value of generated bit bₙ₊1 and adds the signal to the input signal zᵢ to generate a composite signal. The amplifier 5 generates an amplified signal uₙ₊₁ by β-multiplying (β>1) the composite signal generated by the feedback unit 3. The quantizer 7 quantizes the amplified signal uₙ₊₁ using a quantization function Q_{ν}(x) of a quantization threshold ν expressed by an equation (1) and generates a bit bₙ₊₁.

$$\begin{matrix}[ Formula 1 ] & \\ {Q}_{υ} ( x ) = \{ \begin{matrix}0 , & x < υ \\ 1 , & x \geq υ\end{matrix} & ( 1 )\end{matrix}$$

The feedback unit 3 includes a power source 9, a signal generation unit 11, a delay unit 13, and an adder 15. The power source 9 generates a power source signal. The signal generation unit 11 generates a feedback signal from at least the amplified signal uₙ₊₁ in a case of bᵢ₊₁=0, and the signal generation unit 11 generates the feedback signal from the amplified signal uₙ₊₁ and the power source signal in a case of bᵢ₊₁=1. The delay unit 13 delays the feedback signal. The adder 15 generates the composite signal by adding the signal delayed by the delay unit 13 to the input signal zᵢ.

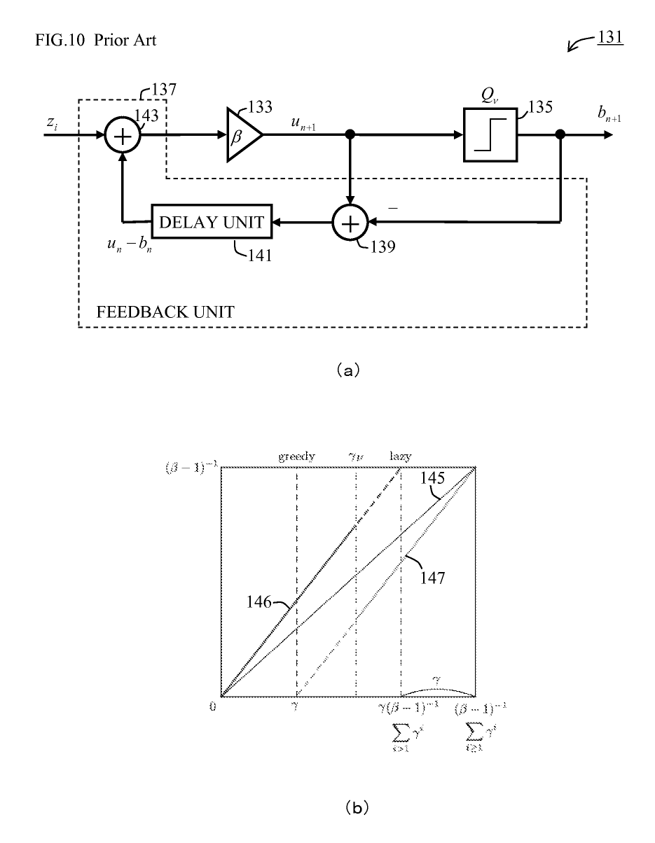

The optimum design of the quantizer and a characteristic equation of β will be described. As illustrated in FIG. 10(b), in β-expansion, [0, (β−1)⁻¹)→[0, (β−1)⁻¹) is obtained as long as νε[1, (β−1)⁻¹). Therefore, x=Σ∞bᵢγⁱ is obtained to enable A/D conversion. The expansion in a case of ν=1 is called greedy expansion, and the expansion in a case of ν=(β−1)⁻¹ is called lazy expansion. When xε[1, (β−1)⁻¹) is β-expanded by L bits, x can be expressed by an equation (2). In this case, γ=1/β. An interval I in which x exists is expressed by an equation (3). The equation (3) indicates that a ratio of a width of a successive (L−1)th subinterval obtained by repetition of β-conversion is equal to γ.

In the conventional β-conversion method, a fixed value x_{Daub} of x is set to a lower limit of the interval as expressed by an equation (4). In this case, a quantiser tolerance is νγ^{L} as expressed by an equation (5).

On the other hand, the present inventors proposed that a fixed value X_{L,C} of x is set to the middle of the interval as expressed by an equation (6) (“cautious” expansion that is neither the greedy expansion nor the lazy expansion). In such a case, the quantiser tolerance is (β−1)⁻¹γ^{L}/2 as expressed by an equation (7). In a case of β>3/2, the tolerance in the equation (7) is improved by 3 dB compared with the tolerance in the equation (5).

A map N_{β,ν}(x) stays in an interval [ν−1, ν) through a transient state. The quantization error in this case is expressed by an equation (8).

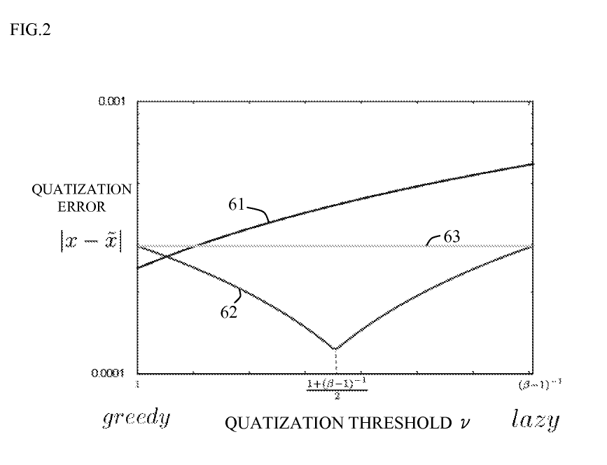

FIG. 2 is a view illustrating the quantization error for the quantization threshold ν in a steady state when the lower limit of the interval is set to the decoded value (line 61), a steady state when the middle point of the interval is set to the decoded value (line 62), and a transient state when the middle point of the interval is set to the decoded value (line 63). Generally, it is recognized that the decoded value of the greedy expansion is better than the decoded value of the lazy expansion. However, as indicated by the line 61, this is caused by use of the fixed value x_{Daub}. As can be seen from FIG. 2, the middle point of the interval is effectively used as the decoded value.

The characteristic equation of β of Daubechies is expressed by an equation (9). On the other hand, the characteristic equation of β of the present inventors is expressed by an equation (10). In this case, bᵢ and cᵢ (i=1, . . . , L) indicate series of L-bit expansion by the signal converter for x and y (y=1−x), respectively.

$$\begin{matrix}[ Formula 2 ] & \\ x = {\sum }_{i = 1}^{L} {b}_{i} {γ}^{i} + {γ}^{L} {N}_{β , v}^{L} ( x ) , {N}_{β , v} ( x ) = \{ \begin{matrix}β x , & x ∈ [ 0 , \frac{v + 1}{β} ) \\ β x - 1 , & x ∈ [ \frac{v + 1}{β} , \frac{1}{β - 1} )\end{matrix} & ( 2 ) \\ I = [ {\sum }_{i = 1}^{L} {b}_{i} {γ}^{i} , {\sum }_{i = 1}^{L} {b}_{i} {γ}^{i} + {( β - 1 )}^{- 1} {γ}^{L} ) & ( 3 ) \\ {x}_{Daub} = {\sum }_{i = 1}^{L} {b}_{i} {γ}^{i} & ( 4 ) \\ \vert x - {x}_{Daub} \vert \leq v {γ}^{L} & ( 5 ) \\ {x}_{L , C} = {\sum }_{i = 1}^{L} {b}_{i} {γ}^{i} + \frac{{( β - 1 )}^{- 1} {γ}^{L}}{2} & ( 6 ) \\ \vert x - {x}_{L , C} \vert \leq \frac{{( β - 1 )}^{- 1} {γ}^{L}}{2} & ( 7 ) \\ \vert x - {x}_{L , C} \vert \leq {γ}^{L} \{ \vert υ - \frac{{( β - 1 )}^{- 1} + 1}{2} \vert + \frac{1}{2} \} & ( 8 ) \\ {P}_{Daub} ( γ ) = 1 - {\sum }_{i = 1}^{L} ( {b}_{i} + {c}_{i} ) {γ}^{i} = 0 & ( 9 ) \\ {P}_{β} ( γ ) = 1 - {\sum }_{i = 1}^{L} ( {b}_{i} + {c}_{i} ) {γ}^{i} \frac{{γ}^{L + 1}}{( 1 - γ )} = 0 & ( 10 )\end{matrix}$$

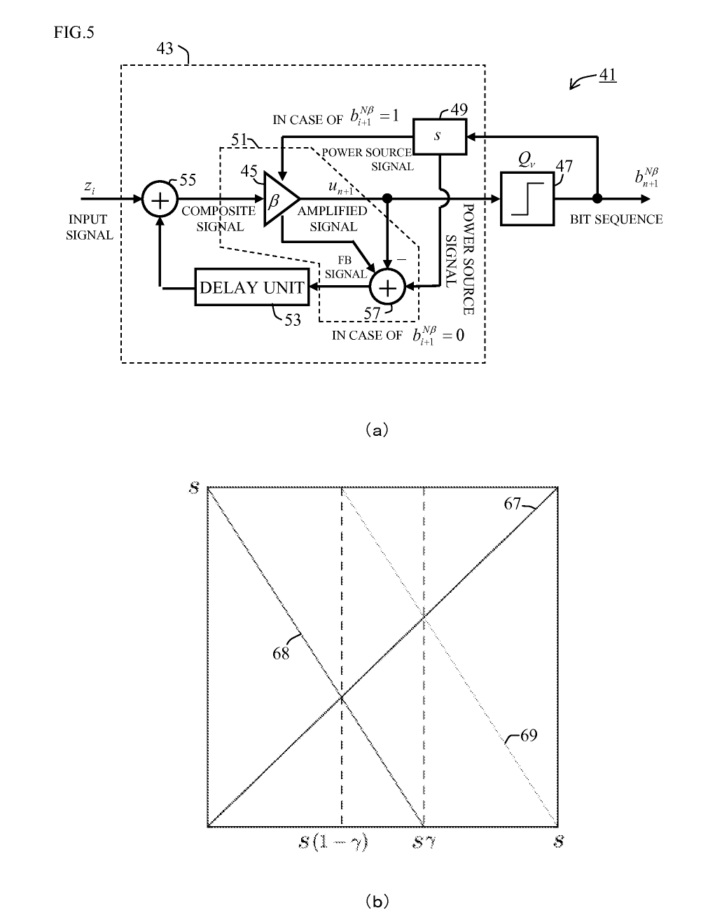

In FIG. 1, the signal generation unit 11 may generate the feedback signal using the signal obtained by multiplying the amplified signal uₙ₊₁ by −1. As described later with reference to FIG. 5 and other figures, such negative β-encoder realize more stable A/D conversion and D/A conversion.

The power source 9 is a voltage source, a current source, or the like. For example, the power source 9 may be a constant voltage source that generates a constant voltage, a voltage source that can generate different voltages according to time, or a voltage source that generates different voltages according to the value of the generated bit bₙ₊₁.

The amplifier 5, the quantizer 7, the signal generation unit 11, the delay unit 13, and the adder 15 may partially or entirely be realized by use of a computer.

### Second Embodiment

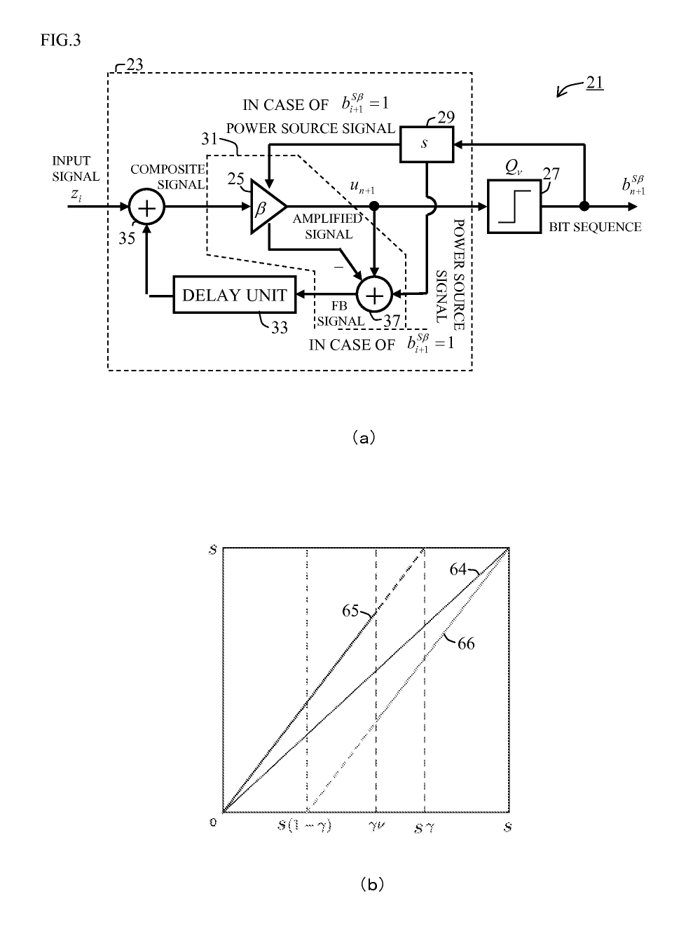

In the present embodiment, a scaled β-encoder (hereinafter referred to as an “S-encoder”) will be described. FIG. 3(a) is a schematic block diagram illustrating a signal converter 21 as an example of the S-encoder, and FIG. 3(b) is a view illustrating a map of the signal converter 21. In FIG. 3(a), a feedback unit 23, an amplifier 25, and a quantizer 27 correspond to the feedback unit 3, the amplifier 5, and the quantizer 7 in FIG. 1, respectively. A power source 29, a signal generation unit 31, a delay unit 33, and a first adder 35 of the feedback unit 23 in FIG. 3(a) correspond to the power source 9, the signal generation unit 11, the delay unit 13, and the adder 15 of the feedback unit 3 in FIG. 1, respectively. The signal generation unit 31 of FIG. 3(a) includes the amplifier 25 and a second adder 37. A power source signal generated by the power source 29 is a bit-control constant power source of the quantizer 27. It is assumed that a parameter (for example, a parameter indicating a voltage in the constant voltage source) of the power source signal is 0 when the generated bit is 0, and it is also assumed that the parameter of the power source signal is s when the generated bit is 1. FIG. 3(a) illustrates the S-encoder of a scale s where s is a scale parameter.

In the signal generation unit 31, when a logic value bᵢ₊₁^{Sβ} generated by the quantizer 27 is 0, the second adder 37 generates the feedback signal without adding any signal to the amplified signal uₙ₊₁. When the logic value bᵢ₊₁^{Sβ} generated by the quantizer 27 is 1, the second adder 37 generates the feedback signal by adding the amplified signal uₙ₊₁, the power source signal generated by the power source 29, and the signal which is the power source signal β-multiplied by the amplifier 25.

Conventionally, the stability to the fluctuation of the threshold has been restricted by the parameter β of the amplifier 133 in FIG. 10. More specifically, a quantiser tolerance σ_{β} is σ_{β}=|[1, (β−1)=(β−1)⁻¹−1.

In the present embodiment, for s>1, a map S_{β,ν} which can perform the A/D conversion in xε[0, s) is introduced by an equation (11). In this case, νε[s(β−1), s). FIG. 3(b) is a view illustrating the map S_{β,ν}. The map S_{β,ν} adopts y=x (line 64) and other two lines either of which is used depending on whether the value of x is less than or more than x=γν. The two lines are a line connecting the origin and (sγ, s) (line 65) and a line connecting (s(1−γ), 0) and (s, s) (line 66). In a case of setting s=(β−1)⁻¹ in an input range [0, s) of the S-encoder, S-encoder is consistent with the β-encoder.

When the sampled value is set to a range of 0<x<1, the signal becomes 0<S_{β,ν}(x)<s by the map S_{β,ν} after the negative feedback is applied once. In the signal converter 21, the negative feedback is performed L times where the value after each of the feedbacks falls within the interval (0, s), and the quantizer 27 generates the logic value 0 or 1 every time depending on the magnitude relationship between the value of the order of the generated γ^{L} and ν. As a result, a computation process of the β-expansion can be realized.

The quantiser tolerance is σ_{β,ν}=s(2−β) in the map S_{β,ν}. Therefore, when s is set to σ_{β,s}(2−β) with respect to the quantiser tolerance σ_{β,s} (for example, the quantiser tolerance of the quantizer), the stability can be secured by s, and the design can be made according to the quantiser tolerance of the quantizer.

The optimum design of the amplifier 25 will further be described. When xε[1, (β−1)⁻¹) is expanded by the S-encoder, x can be expressed by an equation (12). The equation (12) indicates that S^{L}_{β,ν,s}(x) is obtained by repeating the mapping L times. Because S^{L}_{β,ν,s}(x) is included in the interval [0, s), an interval I_{L,β,s} in which x exists in performing the expansion with the L bits is expressed by an equation (13). Therefore, a width |I_{L,β,s}| of the interval is sγ^{L}, and the accuracy is improved most when sγ^{L} is minimized. In a case of the tolerance σ_{β,s}=a, sγ^{L}=γ^{L}a/(2−β) holds, and an equation (14) is obtained when the width |I_{L,β,s}| of the interval is differentiated with respect to β. Therefore, the value of β at which the quantization error is the minimum is expressed by an equation (15). Accordingly, the optimum design of the amplifier can be made according to the bit budget.

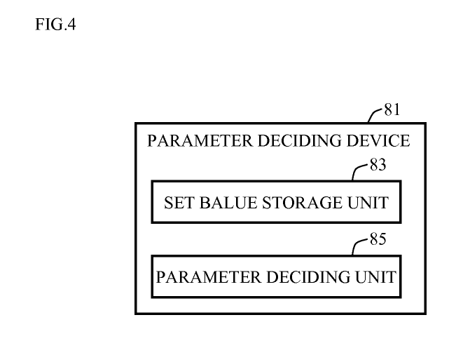

Consequently, either setting s to σ_{β,s}/(2−β) where σ_{β,ν} is the quantiser tolerance or setting the parameter β of the amplifier to 2L/(L+1) where L is the bit budget, or both of them may be realized by use of computer. FIG. 4 is a schematic block diagram illustrating an example of a parameter deciding device 81 that decides a parameter. The parameter deciding device 81 includes a set value storage unit 83 and parameter deciding means 85. The quantiser tolerance σ_{β,ν} and the bit budget L are stored in the set value storage unit 83. The parameter deciding means 85 sets s to σ_{β,s}/(2−β), that is, σ_{β,s}(L+1)/2, and sets the parameter β of the amplifier to 2L/(L+1).

As described above, in the conventional β-encoder, the logic value is fed back by referring to FIG. 10. The S-encoder of the present embodiment includes the power source 29, and the S-encoder has a plurality of feedback signals. Because the plurality of feedback signals exist in FIG. 3, high-level adjustment is required.

Here, s may be set to 1 and β may be set to 2−1/σ_{β,s} where σ_{β,s} is the threshold fluctuation, when the fluctuation of the parameter ν of the quantizer 27 can be so suppressed that s<1 can be realized.

For the L-bit decoded value x_{L,s} of the S-encoder, the maximum error is similar to that of x_{L,C}.

$$\begin{matrix}[ Formula 3 ] & \\ {S}_{β , υ} ( x ) := \{ \begin{matrix}β x , & x ∈ [ 0 , υγ ) \\ s - β ( s - x ) , & x ∈ [ υγ , s )\end{matrix} & ( 11 ) \\ x = s ( β - 1 ) {\sum }_{i = 1}^{L} {b}_{i}^{S β} {γ}^{i} + {γ}^{L} {S}_{β , υ , s}^{L} ( x ) & ( 12 ) \\ {I}_{L , β , s} ( {b}_{i}^{S β} ) = [ s ( β - 1 ) {\sum }_{i = 1}^{L} {b}_{i}^{S β} {γ}^{i} , s ( β - 1 ) {\sum }_{i = 1}^{L} {b}_{i}^{S β} {γ}^{i} + s {γ}^{L} ) & ( 13 ) \\ \frac{d \vert {I}_{L , β , s} ( {b}_{i}^{S β} ) \vert}{d β} = \frac{a {β}^{- L - 1}}{{( 2 - β )}^{2}} \{ β - L ( 2 - β ) \} & ( 14 ) \\ {β}_{opt} = \frac{2 L}{L + 1} & ( 15 )\end{matrix}$$

### Third Embodiment

Next in the present embodiment, a scaled β-encoder in which the β-expansion is performed with a negative real number being set as a radix (hereinafter referred to as an “R-encoder”) will be described. FIG. 5(a) is a schematic block diagram illustrating an outline of a signal converter 41 as an example of the scaled β-encoder to which a negative p-map is introduced, and FIG. 5(b) is a view illustrating a map of the signal converter 41. In FIG. 5(a), a feedback unit 43, an amplifier 45, and a quantizer 47 correspond to the feedback unit 3, the amplifier 5, and the quantizer 7 in FIG. 1, respectively. A power source 49, a signal generation unit 51, a delay unit 53, and a first adder 55 of the feedback unit 43 in FIG. 5(a) correspond to the power source 9, the signal generation unit 11, the delay unit 13, and the adder 15 of the feedback unit 3 in FIG. 1, respectively. The signal generation unit 51 in FIG. 5(a) includes the amplifier 45 and a second adder 57. A parameter s is of a power source signal. For example, the parameter s indicates a voltage of the power source signal.

In the signal generation unit 51, when a logic value bᵢ₊₁ generated by the quantizer 47 is 0, the second adder 57 generates a feedback signal by adding a signal obtained by multiplying an amplified signal uₙ₊₁ by −1 and the power source signal s generated by the power source 49. When the logic value bᵢ₊₁ generated by the quantizer 47 is 1, the second adder 57 generates the feedback signal by adding the signal obtained by multiplying the amplified signal uₙ₊₁ by −1 and a signal obtained by β-multiplying the power source signal s generated by the power source 49 with use of the amplifier 45.

Variance V of the quantization error between a sampled value xᵢ and a fixed value x_{L,Ri} thereof having a sample number i (1≦i≦N) is defined by an equation (16). Because the middle point of the interval is selected as the fixed value, the variance V is large in a case where ν=1 (greedy expansion) and in a case where ν=(β−1)⁻¹ (lazy expansion).

Here, a negative β-map R(x) of the scale s expressed by an equation (17) is introduced. FIG. 5(b) is a view illustrating the map R(x). The map R(x) adopts y=x (line 67), a line (line 68) connecting (0, s) and (sγ, 0), and a line (line 69) connecting (s(1−γ), s) and (s, 0). If s=(β−1)⁻¹ for an input range [0, s) of the R-encoder, R-encoder is consistent with the β-encoder.

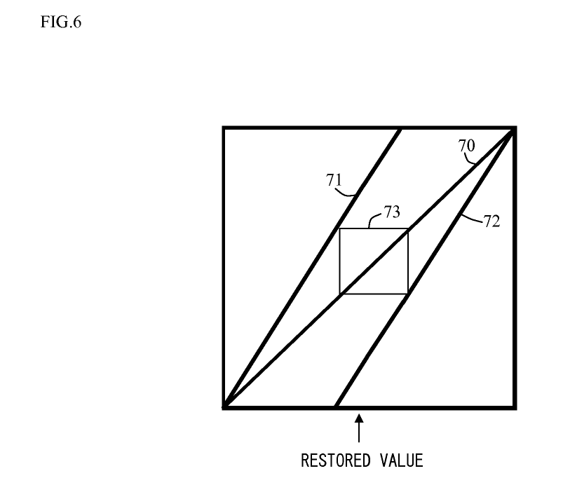

Next, an invariant subinterval is discussed. FIG. 6 is a view illustrating the invariant subinterval of positive β-expansion. In the invariant subinterval of the positive β-expansion, because the middle value is a restored value, average error is large if the invariant subinterval is shifted to an end (for the greedy expansion and the lazy expansion). That is, the invariant subinterval of the β-expansion is [ν−1, ν), and the invariant subinterval [0, 5) is obtained when β=1, 2. However, the invariant subinterval is only a portion of a width 1 of the subinterval. For example, the bit expansion is performed in the interval [0, 1) for the greedy expansion, in the interval [4, 5) for the lazy expansion, and in the middle subinterval of the interval [0, 5) for cautious. In order to perform normal bit expansion, a transition to the steady state should be made as early as possible. When a sampled value x is uniformly distributed, cautious operated in the middle portion is excellent. Therefore, the invariant subinterval is shifted to the middle portion in an ideal state (see an area 73 in FIG. 6).

Table 1 indicates an invariant subinterval under the map R(x). As indicated in Table 1, the invariant subinterval of the map R(x) is a function of ν, and each invariant subinterval is located in the middle of the interval (0, s). The average error for the middle invariant subinterval is substantially equal to that of the positive β-expansion, and the average error is improved because the invariant subinterval is extended in the cases of the greedy expansion and the lazy expansion.

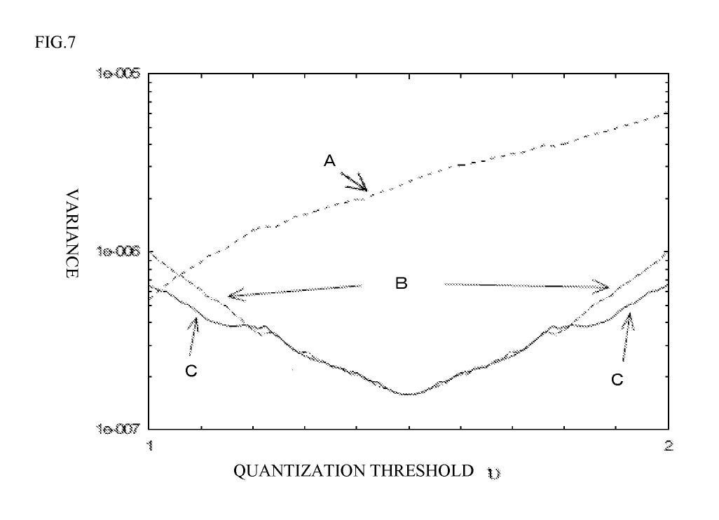

The operation of the signal converter 41 in FIG. 5(a) will more specifically be described. Set for the sampled value x ε[0, 1] is =(x)ε{0, 1}. When x is given, the amplifier 45 sets u₁=βx. The quantizer 47 sets b₁^{Nβ}=1 in a case where u₁>ν and sets b₁^{Nβ}=0 in a case where u₁≦ν (that is, b₁^{Nβ}=Q_{ν}(u₁)). When the operation is repeatedly performed for i≧1, uᵢ₊₁=s (bᵢ^{Nβ}β+bᵢ^{NβC})−uᵢ and bᵢ₊₁^{Nβ}=Q_{ν}(uᵢ₊₁) are obtained. In this case, bᵢ^{NβC}=1−bᵢ^{Nβ}. An equation (18) holds when bᵢ^{Nβ}(i=1, . . . , L) is set to binary expansion of R(x) with respect to xε[0, 1). Because of R^{L}(x)ε[0, s), the middle point of the interval is selected as the fixed value x_{L,R} of x defined by an equation (19). Therefore, the tolerance for approximation error between the sampled value x and the fixed value x_{L,R} thereof is sγ^{L}/2. This is equal to the tolerance of the β-encoder in a case where s=(β−1)⁻¹ (see FIG. 7). However, the variant of the negative β-encoder is improved in a case where ν is set to the neighborhood of the greedy value and the lazy value, even if the fluctuation exists. This is attributed to the fact that, as in the equation (17), the negative feedback needs to be applied in a case where bᵢ₊₁ is equal to 0 or 1, although a feedback amount is varied.

It is assumed that bᵢ^{Nβ} and cᵢ^{Nβ} (i=1, . . . , L) are set as the series of L-bit expansion performed with respect to x and y (y=1−x) by the R-encoder. When dᵢ=bᵢ^{Nβ}+cᵢ^{Nβ} and eᵢ=(1−bᵢ^{Nβ})+(1−cᵢ^{Nβ}) are combined with each other, a characteristic equation of β of the R-encoder is expressed by an equation (20). Estimation of β can be enabled by solving the characteristic equation of β.

FIG. 7 is a view illustrating (A) variance by the β-encoder to which the D/A conversion method of Daubechies is applied, (B) variance by the positive β-encoder, and (C) variance by the negative β-encoder, with respect to the quantization threshold ν. When compared with the (A) β-encoder of Daubechies, the (B) positive β-encoder of the present inventors and the (C) negative β-encoder of the present inventors are largely improved as a whole. The (C) negative β-encoder is substantially equal to the (B) positive β-encoder in the middle portion, and the (C) negative β-encoder is improved for the greedy expansion and the lazy expansion. Thus, the variant of the quantization error of the β-encoder between the sampled value and the fixed value can be improved by the negative β-encoder.

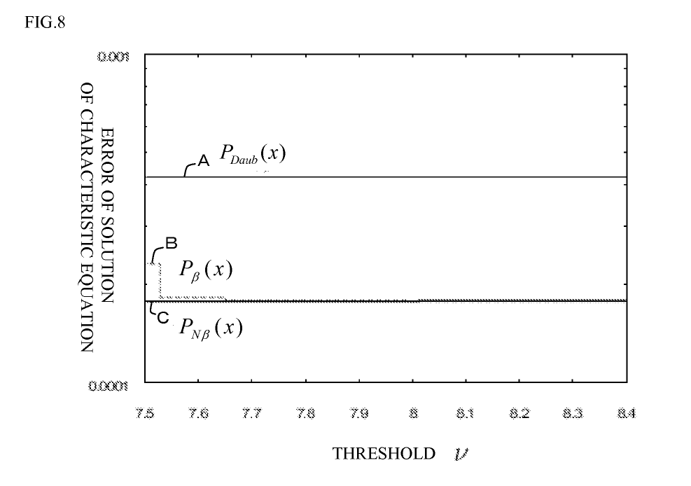

In FIG. 8, a horizontal axis indicates the threshold ν and a vertical axis indicates error between a root of the characteristic equation of β and β, in the cases of (A) a characteristic equation P_{Daub} (γ) of Daubechies, (B) a characteristic equation P_{β}(γ) of the positive β-encoder, and (c) a characteristic equation P_{Nβ}(γ) of the negative β-encoder. When compared with (A) P_{Doub}(γ), (B) P_{β}(γ) and (C) P_{Nβ}(γ) are largely improved. (B) P_{β}(γ) and (C) P_{Nβ}(γ) are substantially equal to each other as a whole.

As described above, the p-expansion in which the negative real number is used as the radix is devised. Besides, the A/D converter and the D/A converter are designed based on the devised β-expansion. Therefore, compared with the conventional β-encoder in which the positive real number is used as the radix, the quantization error is improved, and the instability can be reduced during the mounting of an analog circuit, thereby facilitating the stable circuit mounting.

$$\begin{matrix}[ Formula 4 ] & \\ V := \frac{1}{N} {\sum }_{i = 1}^{N} {\vert {x}_{i} - {x}_{L , Ri} \vert}^{2} & ( 16 ) \\ R ( x ) := \{ \begin{matrix}s - β x , & x ∈ [ 0 , v γ ) \\ β s - β x , & x ∈ [ v γ , s )\end{matrix} υ ∈ [ s ( β - 1 ) , s ) & ( 17 ) \\ x = {( - γ )}^{L} {R}^{L} ( x ) - s {\sum }_{i = 1}^{L} ( {b}_{i}^{N β } β + {b}_{i}^{N β C} ) {( - γ )}^{i} & ( 18 ) \\ {x}_{L , R} = s [ \frac{{( - γ )}^{L}}{2} - {\sum }_{i = 1}^{L} ( {b}_{i}^{N β} β + {b}_{i}^{N β C} ) {( - γ )}^{i} ] & ( 19 ) \\ {P}_{N β} ( γ ) = s \{ {d}_{1} + {\sum }_{i = 1}^{L - 1} ( {d}_{i - 1} - {e}_{i} ) {( - γ )}^{i} + ( 1 - {e}_{L} ) {( - γ )}^{L} \} - 1 = 0 & ( 20 )\end{matrix}$$

TABLE 1

| Threshold ν | Invariant subinterval |
|---|---|
| $( β - 1 ) s < v < \frac{{β}^{2} - β + 1}{β + 1}$ | [βv − (β² − β)s, βs − v) |
| $\frac{{β}^{2} - β + 1}{β + 1} s < v < \frac{2 β - 1}{β + 1} s$ | [s − v, βs − v) |
| $\frac{2 β - 1}{β + 1} s < v < s$ | [s − v, βv − (β − 1)s) |

### DESCRIPTION OF SYMBOLS

1 signal converter, 3 feedback unit, 5 amplifier, 7 quantizer, 9 power source, 11 signal generation unit, 13 delay unit, 15 adder, 21 signal converter, 23 feedback unit, 25 amplifier, 27 quantizer, 29 power source, 31 signal generation unit, 33 delay unit, 35 first adder, 37 second adder, 41 signal converter, 43 feedback unit, 45 amplifier, 47 quantizer, 49 power source, 51 signal generation unit, 53 delay unit, 55 first adder, 57 second adder

1. A signal converter that outputs a bit sequence in response to an input signal, the signal converter comprising:
a feedback unit that generates a composite signal by adding a feedback signal to the input signal, the feedback signal being generated according to a value of the output bit sequence;
an amplifier that multiplies the composite signal by β(β>1) to generate an amplified signal: and
a quantizer that quantizes the amplified signal into a logic value 0 or a logic value 1 and thereby outputs a new bit, wherein
the feedback unit includes:
a power source that generates a power source signal;
a signal generation unit that generates the feedback signal at least by use of the amplified signal when the logic value 0 is output from the quantizer, and generates the feedback signal by use of the amplified signal and the power source signal when the logic value 1 is output from the quantizer; and
an adder that adds the feedback signal to the input signal.

2. The signal converter according to claim 1, wherein
the signal generation unit generates the feedback signal by subtracting the amplified signal from the power source signal when the logic value 0 is output from the quantizer, and
the signal generation unit generates the feedback signal by subtracting the amplified signal from a signal obtained by β-multiplying the power source signal when the logic value 1 is output from the quantizer.

3. The signal converter according to claim 1, wherein
the signal generation unit generates the feedback signal as being equal to the amplified signal when the logic value 0 is output from the quantizer, and
the signal generation unit generates the feedback signal by subtracting a signal obtained by β-multiplying the power source signal from sum of the amplified signal and the power source signal when the logic value 1 is output from the quantizer.

4. The signal converter according to claim 1, wherein
a parameter β of the amplifier is 2L/(L+1) with respect to a number of bits L of the bit sequence output by the signal converter, and/or
a parameter s of the power source signal generated by the power source is σ_{β,s}(L+1)/2 with respect to a quantiser tolerance σ_{βs}.

5. A parameter deciding device that decides a parameter in the signal converter of claim 1, the parameter deciding device comprising:
a set value storage unit that stores a number of bits L of the bit sequence output by the signal converter and a quantiser tolerance σ_{βs} of the signal converter; and
a parameter deciding unit that decides a parameter β of the amplifier of the signal converter and a parameter s of the power source signal generated by the power source of the signal converter by β=2L/(L+1) and s=σ_{β,s}(L+1)/2, respectively, and correcting β=2L/(L+1) and s=σ_{β,s}(L+1)/2 to β=2−1/σ_{β,s} and s=1 when the parameter s satisfies s≦1.

6. A parameter deciding method for a parameter deciding device that decides a parameter in the signal converter of claim 1, wherein
the parameter deciding device includes a set value storage unit that stores a number of bits L of the bit sequence output by the signal converter; and
a parameter deciding unit of the parameter deciding device that decides that a parameter β of the amplifier of the signal converter is 2L/(L+1).

7. A parameter deciding method for a parameter deciding device that decides a parameter in the signal converter of claim 1, wherein
the parameter deciding device includes a set value storage unit that stores a quantiser tolerance σ_{βs} of the signal converter;
the set value storage unit further stores a number of bits L of the bit sequence output by the signal converter or the parameter β of the amplifier of the signal converter; and
a parameter deciding unit of the parameter deciding device decides a parameter s of the power source signal generated by the power source of the signal converter between σ_{β,s}(L+1)/2 and σ_{β,s}/(2−β).

8. A program that causes a computer to perform the parameter deciding method according to claim 6.

9. A computer-readable recording medium in which the program according to claim 8 is recorded.

10. The signal converter according to claim 2, wherein
a parameter β of the amplifier is 2L/(L+1) with respect to a number of bits L of the bit sequence output by the signal converter, and/or
a parameter s of the power source signal generated by the power source is σ_{β,s}(L+1)/2 with respect to a quantiser tolerance σ_{βs}.

11. The signal converter according to claim 3, wherein
a parameter β of the amplifier is 2L/(L+1) with respect to a number of bits L of the bit sequence output by the signal converter, and/or
a parameter s of the power source signal generated by the power source is σ_{β,s}(L+1)/2 with respect to a quantiser tolerance σ_{βs}.

12. A parameter deciding device that decides a parameter in the signal converter of claim 2, the parameter deciding device comprising:
a set value storage unit that stores a number of bits L of the bit sequence output by the signal converter and a quantiser tolerance σ_{βs} of the signal converter; and
a parameter deciding unit that decides a parameter β of the amplifier of the signal converter and a parameter s of the power source signal generated by the power source of the signal converter by β=2L/(L+1) and s=σ_{β,s}(L+1)/2, respectively, and correcting β=2L/(L+1) and s=σ_{β,s}(L+1)/2 to β=2−1/σ_{β,s} and s=1 when the parameter s satisfies s≦1.

13. A parameter deciding device that decides a parameter in the signal converter of claim 3, the parameter deciding device comprising:
a set value storage unit that stores a number of bits L of the bit sequence output by the signal converter and a quantiser tolerance σ_{βs} of the signal converter; and
a parameter deciding unit that decides a parameter β of the amplifier of the signal converter and a parameter s of the power source signal generated by the power source of the signal converter by β=2L/(L+1) and s=σ_{β,s}(L+1)/2, respectively, and correcting β=2L/(L+1) and s=σ_{β,s}(L+1)/2 to β=2−1/σ_{β,s} and s=1 when the parameter s satisfies s≦1.

14. A parameter deciding method for a parameter deciding device that decides a parameter in the signal converter of claim 2, wherein
the parameter deciding device includes a set value storage unit that stores a number of bits L of the bit sequence output by the signal converter; and
a parameter deciding unit of the parameter deciding device that decides that a parameter β of the amplifier of the signal converter is 2L/(L+1).

15. A parameter deciding method for a parameter deciding device that decides a parameter in the signal converter of claim 3, wherein
the parameter deciding device includes a set value storage unit that stores a number of bits L of the bit sequence output by the signal converter; and
a parameter deciding unit of the parameter deciding device that decides that a parameter β of the amplifier of the signal converter is 2L/(L+1).

16. A parameter deciding method for a parameter deciding device that decides a parameter in the signal converter of claim 2, wherein
the parameter deciding device includes a set value storage unit that stores a quantiser tolerance σ_{βs} of the signal converter;
the set value storage unit further stores a number of bits L of the bit sequence output by the signal converter or the parameter β of the amplifier of the signal converter; and
a parameter deciding unit of the parameter deciding device decides a parameter s of the power source signal generated by the power source of the signal converter between σ_{β,s}(L+1)/2 and σ_{β,s}/(2−β).

17. A parameter deciding method for a parameter deciding device that decides a parameter in the signal converter of claim 3, wherein
the parameter deciding device includes a set value storage unit that stores a quantiser tolerance σ_{βs} of the signal converter;
the set value storage unit further stores a number of bits L of the bit sequence output by the signal converter or the parameter β of the amplifier of the signal converter; and
a parameter deciding unit of the parameter deciding device decides a parameter s of the power source signal generated by the power source of the signal converter between σ_{β,s}(L+1)/2 and σ_{β,s}/(2−β).

18. A program that causes a computer to perform the parameter deciding method according to claim 7.
